(19) United States
(12) Patent Application Publication
(10) Pub. No.: US 2025/0254992 A1
(43) Pub. Date: Aug. 7, 2025

(54) ELECTRONIC CHIP COMPRISING STRESSED TRANSISTORS

(71) Applicant: STMicroelectronics International N.V., Geneva (CH)

(72) Inventors: Remy BERTHELON, Crolles (FR); Olivier WEBER, Grenoble (FR)

(73) Assignee: STMicroelectronics International N.V., Geneva (CH)

(21) Appl. No.: 19/035,500

(22) Filed: Jan. 23, 2025

(30) Foreign Application Priority Data
Feb. 1, 2024 (FR) FR2400993

(51) Int. Cl. H10D 86/00; H10B 63/00; H10B 63/10; H10D 10/01; H10D 30/67; H10D 30/69; H10D 84/03; H10D 86/01

(52) U.S. Cl. CPC H10D 86/201; H10D 10/01; H10D 30/6757; H10D 30/792; H10D 84/038; H10D 86/01; H10B 63/10; H10B 63/32

(57) ABSTRACT

The present description concerns a method of manufacturing an electronic chip comprising the successive steps of: providing a semiconductor layer located on an insulator covering a semiconductor substrate; oxidizing first and second portions of the semiconductor layer down to the insulator, to form first oxidized portions and second oxidized portions on the insulator; generating stress in a third portion of the semiconductor layer through which the first and second oxidized portions do not pass, the third portion continuously extending between the second oxidized portions; forming cavities extending at least down to the semiconductor substrate through the second oxidized portions and the insulator; and forming first field-effect transistors in and on top of the third portion.

### CROSS-REFERENCE TO RELATED APPLICATION(S)

This application claims the priority benefit of French patent application number FR2400993, filed on Feb. 1, 2024, entitled “Puce électronique comprenant des transistors contraints,” which is hereby incorporated by reference to the maximum extent allowable by law.

### BACKGROUND

### Technical Field

The present disclosure generally concerns the field of electronic chips and more particularly the field of electronic chips comprising transistors with a stressed channel region, and their manufacturing methods.

The present disclosure may, for example, concern electronic chips further comprising a phase-change memory circuit, and their manufacturing methods.

### Description of the Related Art

A transistor with a stressed channel region, or stressed transistor, is a field-effect transistor in which a semiconductor channel-forming region exhibits mechanical stress. The presence of stress in the channel-forming region (channel region) increases the transistor speed. This type of transistor is generally used in digital circuits.

A phase-change memory is a type of memory in which a phase-change material can take two states, typically crystalline and amorphous states, each corresponding to a stored bit value. Typically, the memory is formed of phase-change memory cells, each storing the value of a bit.

There exists a use for improving electronic chips comprising transistors with a stressed channel region, and in certain cases also a phase-change memory circuit, as well as methods of manufacturing such electronic chips.

In particular, there exists a use for improving, or not releasing, the stress in transistors with a stressed channel region, especially during the electronic chip manufacturing process. There exists a use for improving the performance of the transistors with a stressed channel region of electronic chips.

### BRIEF SUMMARY

An embodiment overcomes all or part of the disadvantages of known electronic chips.

An embodiment overcomes all or part of the disadvantages of known chip manufacturing methods.

An embodiment provides a method of manufacturing an electronic chip, the method comprising the successive steps, consisting of:

providing a semiconductor layer located on an insulator covering a semiconductor substrate;

oxidizing first and second portions of the semiconductor layer down to the insulator, to form first oxidized portions and second oxidized portions on the insulator;

generating stress in a third portion of the semiconductor layer through which the first and second oxidized portions do not pass, the third portion continuously extending between the second oxidized portions;

forming cavities extending at least down to the semiconductor substrate through the second oxidized portions and the insulator; and

forming first field-effect transistors in and on top of the third portion.

An embodiment provides an electronic chip comprising: first, second, and third portions of a semiconductor layer located on an insulator covering a semiconductor substrate, the first and second portions of said semiconductor layer being oxidized down to the insulator, the third portion being stressed, not having the first and second oxidized portions passing through it, and continuously extending between first portions of the second oxidized portions;

cavities extending at least down to the semiconductor substrate through the second oxidized portions and the insulator; and

first field-effect transistors located in and on top of the third portion.

According to an embodiment, fourth portions of the semiconductor layer are formed next to the third portion, each fourth portion being between two of the first oxidized portions or between one of the first oxidized portions and one of the second oxidized portions; and

second field-effect transistors are formed in and on top of the fourth portions.

According to an embodiment, first gates are formed above the third and fourth portions.

According to an embodiment, second gates are formed above the first oxidized portions and insulating gates are formed in line with the second gates above the third portion.

According to an embodiment, the fourth portions are positioned next to the third portion in the width direction of the field-effect transistors.

According to an embodiment, the first transistors have a stressed P channel, and the second transistors have an N channel, for example an unstressed N channel.

According to an embodiment, insulating trenches extend through the semiconductor layer and the insulator down to a level located within the semiconductor substrate, the insulating trenches comprising a first insulating trench between the third portion and the fourth portions.

According to an embodiment, the stress of the third portion results from a change in the composition of the semiconductor layer in said third portion, for example comprises the forming of a silicon-germanium layer on the third portion, followed by thermal treatment.

According to embodiments:

the first oxidized portions are substantially parallel to one another, for example parallel to the width direction of the field-effect transistors; and/or

the second oxidized portions are substantially parallel to one another, for example parallel to the width direction of the field-effect transistors; and/or

the first oxidized portions are positioned between at least two of the second oxidized portions.

According to an embodiment, the semiconductor layer is a silicon layer.

According to an embodiment, the first transistors are of FDSOI type.

According to an embodiment, bipolar transistors are formed in at least a first portion of the cavities, and phase-change memory cells coupled to the bipolar transistors are formed.

According to an embodiment, doped semiconductor emitter, base, and collector regions of the bipolar transistors are formed in first epitaxial semiconductor portions in the at least a first part of the cavities.

According to an embodiment, third gates are formed on second parts of the second oxidized portions between the bipolar transistors.

According to an embodiment, additional field-effect transistors are formed in and on top of second epitaxial semiconductor portions in a second part of the cavities.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1A shows, in partial and simplified top and cross-section views, a structure obtained at a step of an electronic chip manufacturing method;

FIG. 1B shows two partial and simplified cross-section views of the structure of FIG. 1A;

FIG. 2A shows, in partial and simplified top and cross-section views, a structure obtained at another step of the manufacturing method;

FIG. 2B shows two partial and simplified cross-section views of the structure of FIG. 2A;

FIG. 3A shows, in partial and simplified top and cross-section views, a structure obtained at another step of the manufacturing method;

FIG. 3B shows two partial and simplified cross-section views of the structure of FIG. 3A;

FIG. 4A shows, in partial and simplified top and cross-section views, a structure obtained at another step of the manufacturing method;

FIG. 4B shows two partial and simplified cross-section views of the structure of FIG. 4A;

FIG. 5A shows, in partial and simplified top and cross-section views, a structure obtained at another step of the manufacturing method;

FIG. 5B shows two partial and simplified cross-section views of the structure of FIG. 5A;

FIG. 6A shows, in partial and simplified top and cross-section views, a structure obtained at another step of the manufacturing method; and

FIG. 6B shows two partial and simplified cross-sections of the structure of FIG. 6A.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, steps of phase-change memory cell manufacturing are not described in detail, the described embodiments being compatible with current steps of phase-change memory cell manufacturing. Similarly, steps of bipolar or field-effect transistor manufacturing are not described in detail, the described embodiments being compatible with usual steps of bipolar or field-effect transistor manufacturing.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

Unless otherwise specified, ordinal numerical adjectives, such as “first,” “second,” etc., are used only to distinguish elements from one another. In particular, these adjectives do not limit the described devices and methods to a specific order of these elements.

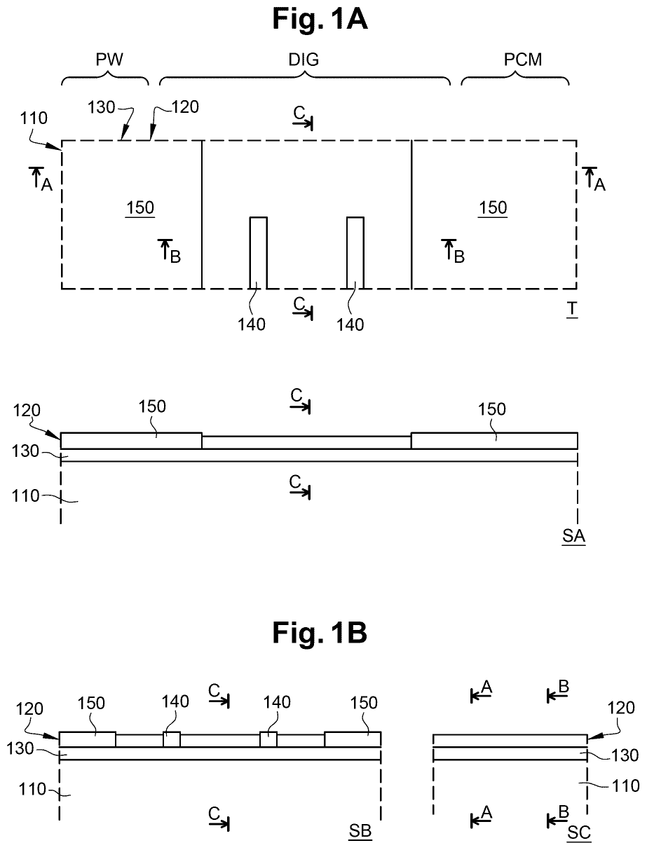

FIGS. 1A, 2A, 3A, 4A, 5A, and 6A each show, by partial and simplified top views T and cross-section views SA along a plane A-A, a structure obtained at a step of an electronic chip manufacturing method. Views T and SA are in correspondence.

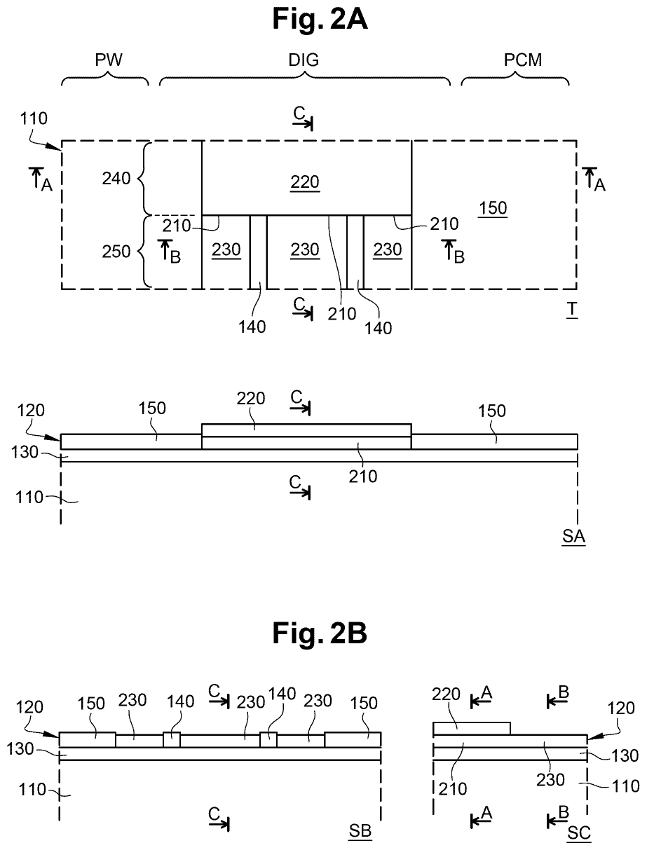

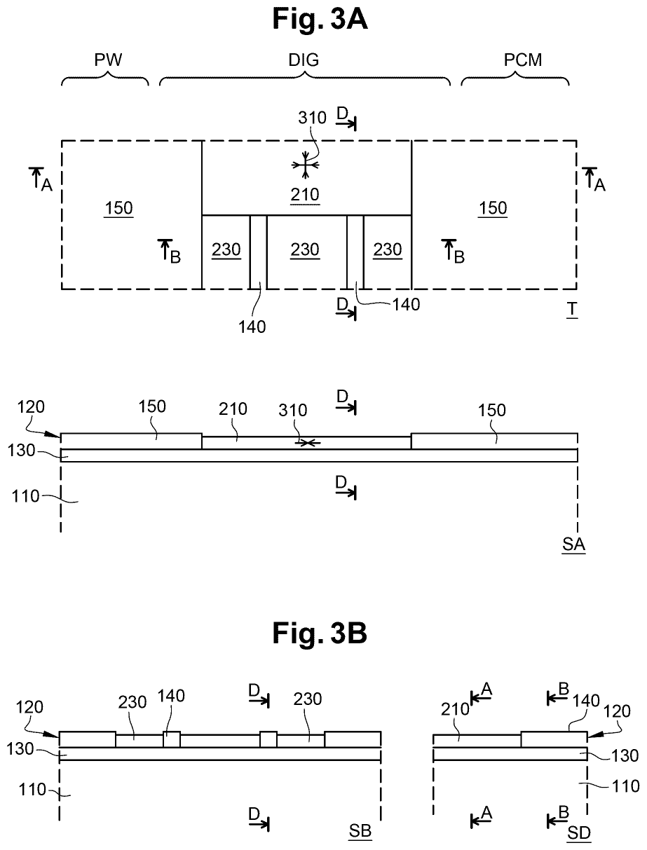

FIGS. 1B, 2B, 3B, 4B, 5B, and 6B each show two partial and simplified cross-section views of the respective structures of FIGS. 1A, 2A, 3A, 4A, 5A, and 6A. Each of FIGS. 1B and 2B shows a cross-section view SB along a plane B-B parallel to plane A-A and a cross-section view SC along a plane C-C orthogonal to planes A-A and B-B. Views SB and SC are in correspondence. FIGS. 3B, 4B, 5B, and 6B each show a cross-section view SB along plane B-B and a cross-section view SD along a plane D-D parallel to plane C-C. Views SB and SD correspond.

By electronic chip, or chip, there is meant a portion of semiconductor substrate 110 or semiconductor wafer, and electronic circuits located in and on top of semiconductor substrate 110. The chip obtained as a result of the following method will comprise, in a part DIG (digital part) of the chip, one or a plurality of digital circuits comprising stressed transistors, and in a part PCM of the chip, a phase-change memory. Preferably, a part PW of the chip will comprise other transistors. These other transistors may be used in power supply circuits intended to supply a voltage to the digital circuits of the chip, from a power supply voltage applied to the chip in order to operate it.

Although parts DIG, PCM, and the possible part PW are juxtaposed in the shown example, these parts may be separated in other examples. In still other examples, the chip may comprise a plurality of parts DIG and/or a plurality of parts PCM and/or a plurality of parts PW.

At the step of FIGS. 1A and 1B, a semiconductor layer 120 is provided on an electrical insulator 130 (or dielectric) covering substrate 110. Semiconductor layer 120, insulator 130, and semiconductor substrate 110 can thus form a so-called silicon-on-insulator, SOI, structure.

Preferably, semiconductor layer 120 is a silicon layer, and insulator 130 is a silicon oxide layer. Substrate 110 may be a portion of a silicon wafer. As an example, semiconductor layer 120 has a thickness in the range from 3 nm to 10 nm.

First and second portions, respectively 140 and 150, of semiconductor layer 120 have been oxidized, forming first oxidized portions 140 and second oxidized portions 150. More precisely, the first and second portions of semiconductor layer 120 are oxidized across the entire thickness of semiconductor layer 120. For this purpose, any current step of semiconductor layer oxidation may be used, typically a thermal oxidation. This step, being current, is not described in detail herein. In particular, a mask protecting from oxidation portions of semiconductor layer 120 which are not desired to be oxidized during this step is not shown. Due to the oxidation, the oxidized portions have a thickness greater than the thickness of semiconductor layer 120.

The first oxidized portions 140 may be located in the digital part DIG of the future chip. Preferably, the first oxidized portions 140 have a widthwise elongation direction, corresponding to the direction of cross-section C-C. The first oxidized portions 140 then form oxide bars parallel to one another, which may have an electrical insulation function. The first oxidized portions 140 do not extend across the entire width of the semiconductor layer 120. The first oxidized portions 140 do not extend in a future stressed portion of semiconductor layer 120. Thus, in the shown example, in view T of FIG. 1A, the first oxidized portions 140 can be seen in the lower half, but not in the upper half, and the first oxidized portions 140 can be seen in view SB of FIG. 1B, but not in view SA of FIG. 1A, cross-section A-A being made in a region where there are no first oxidized portions. Although two first oxidized portions 140 are formed in the shown example, preferably, more than two first portions 140 are oxidized.

The second oxidized portions 150 may be partly located in part PCM intended to contain the phase-change memory. In the example where a part PW is provided, the second oxidized portions 150 may be at least partly located in part PCM and in part PW.

Preferably, in part PCM and, optionally, part PW, the entire semiconductor layer 120 is oxidized. In other words, the second oxidized portions 150 occupy the entire parts PCM and, possibly, PW.

Second oxidized portions 150 may also be provided in part DIG, for example on two opposite sides of part DIG. In the shown example, the second oxidized portions 150 cover the entire parts PCM and PW and extend over part DIG.

The first oxidized portions 140 may be positioned between the second oxidized portions 150.

The first and second oxidized portions may form a super shallow trench isolation (SSTI), to insulate future transistors from one another.

At the step of FIGS. 2A and 2B, silicon-germanium 220 has been formed by epitaxy on a non-oxidized third portion 210 of semiconductor layer 120. The third portion 210 is included in, for example corresponds to, the region of the semiconductor layer which comprises no oxidized first portions 140.

More precisely, the epitaxy is carried out on the upper surface side of the structure (in the orientation of the cross-section views), also called front surface, which corresponds to the upper surface of the semiconductor layer 120. As an example, the thickness of epitaxial silicon-germanium 220 is in the range from 5 to 20 nm.

The third portion 210 extends between the second oxidized portions 150, that is, extends from one of the second oxidized portions 150 to another of the second oxidized portions 150. In other words, the third portion 210 is delimited, on each of two opposite sides, by one of the second oxidized portions 150. Further, the third portion 210 extends continuously between the second oxidized portions 150. By continuous, it is meant that the third portion does not have the first oxidized portions passing through it.

The third portion 210 is located, in top view, in a first strip 240. Another third portion, not shown, may be located in another strip parallel to the first strip 240. Other third portions may each be located in another strip parallel to the first strip 240.

During the epitaxy, a mismatch between crystal lattices causes, in epitaxial silicon-germanium 220, compressive stress parallel to the front surface (that is, horizontal in the orientation of the cross-section views).

Preferably, next to the third portion 210, for example next to it widthwise, semiconductor layer 120 comprises fourth portions 230 which are not oxidized and not covered with epitaxial silicon-germanium. The fourth portions 230 are included in, for example correspond to, a region of the semiconductor layer through which the first oxidized portions 140 pass.

Each fourth portion 230 extends between some of the first and second oxidized portions, that is, extends from one of the first and second oxidized portions 140 and 150 to another of the first and second oxidized portions 140 and 150. In other words, each of the fourth portions 230 is delimited, on two opposite sides, by two portions among the first and second oxidized portions 140 and 150. The fourth portions 230 are located, in top view, in a second strip 250 parallel to the first strip 240. The first and second strips 240 and 250 are located side by side, for example side by side widthwise. The second strip 250 is substantially perpendicular to the first oxidized portions 140. Other fourth portions, not shown, may be located in another strip parallel to the second strip 250. Other fourth portions may be located in other strips parallel to the second strip 250.

The fourth portions 230, not intended to be covered with epitaxial silicon-germanium, may be covered, during the epitaxy, by any conventional mask adapted to protecting at least these fourth portions, for example, a mask adapted to protecting regions of semiconductor layer 120 comprising the first and second oxidized portions 140, 150 and the fourth portions 230 while leaving the third portion 210 exposed, so that the epitaxial silicon-germanium grows from the third portion but does not grow from the fourth portions.

At the step of FIGS. 3A and 3B, a thermal treatment has been performed, to oxidize the epitaxial silicon-germanium. Generally, the regions not to be treated are protected by a protective layer, such as a silicon nitride (SiN) layer. The silicon of silicon-germanium 220 preferentially oxidizes, and the germanium of silicon-germanium 220 migrates to the third portion 210 of semiconductor layer 120. This results in an intensification and in a transfer into the third portion 210 of the stress initially present in silicon-germanium 220.

As a result, compressive stress 310 has been generated in the third portion 210. Compressive stress 310 is in both horizontal directions (in the orientation of the cross-section views). To generate stress 310, the composition of the third portion 210 has been modified. In other words, the third portion 210 acquires a composition different from the fourth portions 230, that is, preferably, the third portion 210 is made of silicon-germanium, and the fourth portions 230 are made of silicon.

The fact that the third portion 210 does not have the first oxidized portions 140 passing through it enables to avoid a releasing of stress 310, which releasing could occur if the first oxidized portions were to pass through the third portion. Further, if the oxidized first portions were present within the third portion, all or part of the oxide of these first portions could be consumed during the epitaxy of silicon-germanium and during the removal of the silicon oxide layer obtained by the thermal treatment, which would at least partly cancel the function of insulation of these first portions.

Preferably, the front surface of the structure is then cleaned to remove what remains of the silicon oxide layer obtained during the thermal treatment.

The specific above-described example of stress generation in the third portion 210 is not limiting. The described embodiments are compatible with current methods of stress generation in one or a plurality of portions of a semiconductor layer.

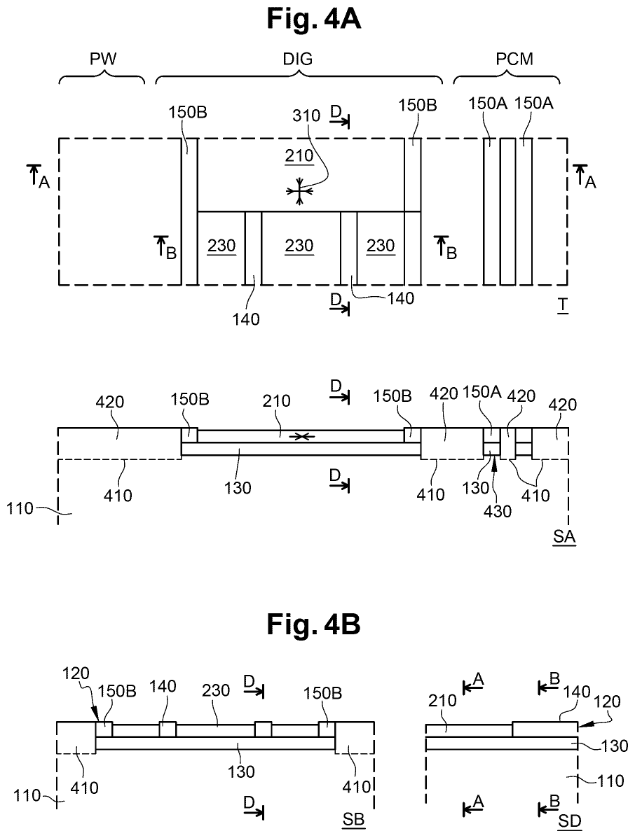

At the step of FIGS. 4A and 4B, there are etched from the front surface of semiconductor layer 120, in particular from the front surfaces of the second oxidized portions 150, cavities 410 extending all the way to substrate 110 through the second oxidized portions 150 and insulator 130. Cavities 410 reach substrate 110 and may penetrate into substrate 110.

Preferably, in the part PCM intended to comprise the future phase-change memory, stacks 430 of parts 130A of the insulator 130 and of parts 150A (second parts) of the second oxidized portions 150 are left in place. Cavities 410 delimit stacks 430.

Although only two stacks 430 are provided in the shown example, the number of stacks 430 is preferably greater than two. Preferably, stacks 430 have, in top view, shapes of strips parallel to the first oxidized portions 140. Stacks 430 thus form electrically-insulating bars.

Preferably, in the part DIG intended to comprise the future stressed transistors, there are also left in place, against the third portion 210 and the fourth portions 230, parts 150B (first parts) of the second oxidized portions 150. In other words, the third and fourth portions 210 and 230 are delimited lengthwise, corresponding to the direction of cross-sections A-A and B-B, by the parts 150B of the second oxidized portions 150.

A semiconductor has then been formed by epitaxy in cavities 410. The epitaxial semiconductor is typically the same as that of substrate 110, preferably silicon. Each cavity 410 is filled with an epitaxial semiconductor portion 420. Preferably, the epitaxial semiconductor portions 420 reach a level located above (in the orientation of the cross-section views) the upper level of the third portion 210 and the upper level of the fourth portions 230. In other words, the epitaxial semiconductor portions 420 extend beyond the levels of the front surfaces of the third and fourth portions 210 and 230. In part PCM, the epitaxial semiconductor portions 420 are electrically insulated from one another by stacks 430.

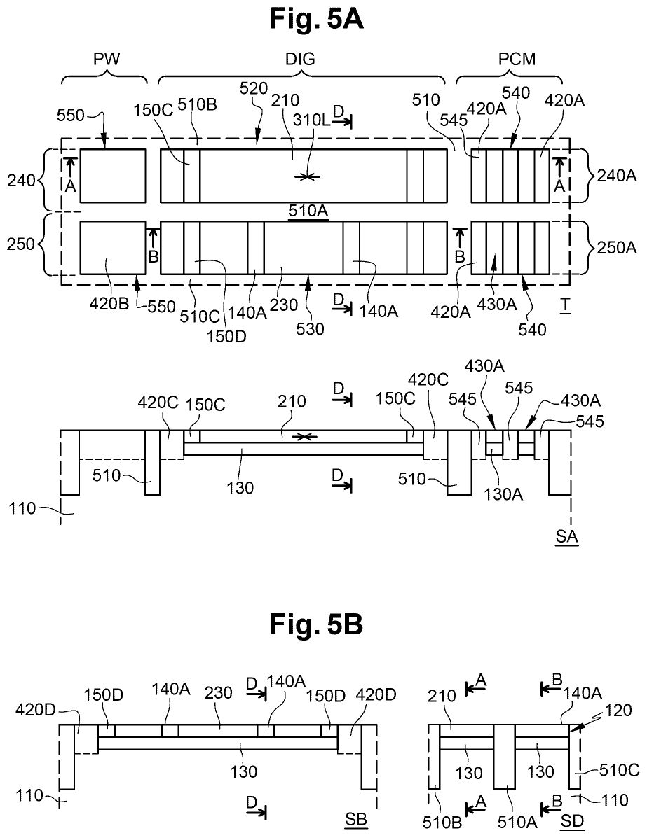

At the step of FIGS. 5A and 5B, preferably, all the elements of the structure of FIGS. 4A and 4B located above the level of the upper surface of the fourth portions 230 have been removed. For this purpose, a current chemical-mechanical polishing step may be implemented.

Preferably, there have been formed insulating trenches 510, that is, trenches filled with an electrical insulator, preferably silicon oxide. In other words, a step of etching of the trenches, followed by a step of filling with the electrical insulator, are successively implemented. These steps are not described in detail herein, the described embodiments being compatible with current etching and filling steps for forming insulating trenches. The insulating trenches may form shallow trench isolation (STI) trenches. Preferably, the insulating trenches 510 separate parts DIG and PCM, and parts DIG and PW, from one another.

Insulating trenches 510 extend from the front surface of semiconductor layer 120, run through the level occupied by the first, second, third, and fourth portions 140, 150, 210, 230 of semiconductor layer 120, and through insulator 130, all the way to a level located within substrate 110.

The locations of insulating trenches 510 are selected so that the insulating trenches 510 surround (in top view) regions of the chip. The etching of insulating trenches 510 leaves in place a central part of each of the third and fourth portions 210 and 230, in other words, insulating trenches 510 decrease the dimensions of the third and fourth portions. The etching leaves in place parts 140A of the first oxidized portions 140 and parts 430A of stacks 430.

Among the regions of the chip surrounded by insulating trenches 510, one or a plurality of regions 540 located in part PCM comprise semiconductor portions 420A (first epitaxial semiconductor portions) formed by part of the epitaxial semiconductor portions 420. Doped emitter, base, and collector semiconductor areas (not shown in detail) of a bipolar transistor 545 are formed in each of semiconductor portions 420A. These areas may be formed by doping during the epitaxy or, preferably, by doping of semiconductor portions 420A. Bipolar transistors 545 are for example NPN-type transistors. The doped areas of bipolar transistors 545 are insulated from one another by parts 430A of stacks 430.

Among the regions surrounded by insulating trenches 510, a region 520 located in part DIG comprises the central part of the third portion 210. Preferably, region 520 comprises one or a plurality of semiconductor portions 420C formed by a part of the epitaxial semiconductor portions 420. The semiconductor portions 420C of region 520 are electrically insulated from the third portion 210 by parts 150C of the second oxidized portions 150. Parts 150C correspond to the parts 150B of the second oxidized portions 150 which have remained in place in region 520 after the forming of insulating trenches 510.

Among the regions surrounded by insulating trenches 510, a region 530 located in part DIG comprises the parts 140A of the first oxidized portions 140 and the central part of the fourth portions 230. Preferably, region 530 comprises one or a plurality of semiconductor portions 420D formed by part of the epitaxial semiconductor portions 420. The semiconductor portions 420D of region 530 are insulated from the fourth portions 230 by parts 150D of the second oxidized portions 150. Parts 150D correspond to the parts 150B of the second oxidized portions 150 which have remained in place in region 530 after the forming of insulating trenches 510.

Preferably, among insulating trenches 510, an insulating trench 510A extends, in top view, parallel to the first and second strips 240 and 250 and astride strips 240 and 250. Insulating trench 510A is thus located astride the locations of the third portions 210 and the fourth portions 230, or between the central parts of the third and fourth portions.

Insulating trenches 510 are preferably formed after the generation of stress 310. This results in that the third portion 210 can extend in insulating trench 510A before the filling of the trenches with the insulator, which releases the stress 310 in the direction orthogonal to the first strip 240. However, due to the absence of the first oxidized portions 140 in the third portion 210, as explained hereabove, it has advantageously been avoided for the stress in the direction of the first strip 240 to be released.

Thus, after formation of the insulating trenches 510, 510A, the third portion 210 exhibits compressive stress 310L in the longitudinal direction of the first strip 240, and is substantially unstressed in the transverse direction of the first strip 240.

Preferably, among insulating trenches 510, an insulating trench 510B is located with respect to the third portion 210 on the side opposite to insulating trench 510A, extends parallel to the first strip 240, and delimits the third portion 210. Thus, region 520 is located in a central part 240A of the first strip 240.

Preferably, among insulating trenches 510, an insulating trench 510C is located with respect to the fourth portions 230 on the side opposite to insulating trench 510A, extends parallel to the second strip 250, and delimits the fourth portions 230. Thus, region 530 is located in a central part 250A of the second strip 250.

Preferably, among the chip regions surrounded by insulating trenches 510, a region 550 located in part PW comprises semiconductor portions 420B (second epitaxial semiconductor portions) formed by part of the epitaxial semiconductor portions 420.

In the shown example, insulating trenches 510A, 510B, and 510C, which extend parallel to the central parts 240A, 250A of the first and second strips 240, 250, extend in parts PCM and PW. As a result, part PCM comprises a region 540 in each of the central parts 240A, 250A, and part PW comprises a region 550 in each of the central parts 240A, 250A.

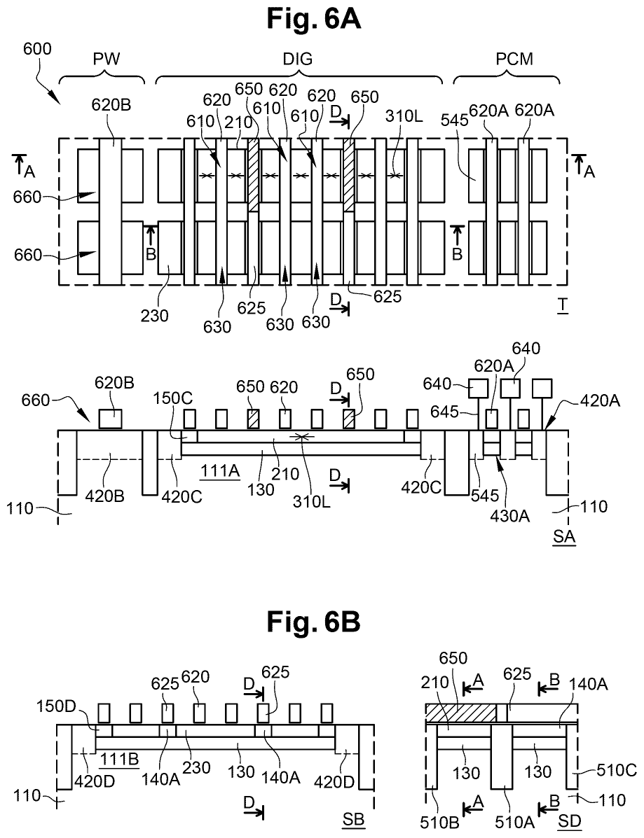

At the step of FIGS. 6A and 6B, field-effect transistors 610 are formed in and on top of the third portion 210. More specifically, there are formed, on the third portion 210, gates 620 (first gates), preferably elongated orthogonally to the direction of the first strip 240. Since there are no first oxidized parts 140 within the third portion 210, the third portion may form a continuous RX area. Transistors 610 may then be insulated from one another by gate-ties or tying gates 650 positioned above the third portion and in line with the first oxidized parts 140 widthwise. Between two insulating gates 650, the third portion 210 may comprise a plurality of transistors 610, for example transistors having a common drain-source terminal. Preferably, gates 620, 650 are evenly spaced apart, that is, substantially the same space may be comprised between two gates 620 or between a gate 620 and an insulating gate 650.

The parts of the third portion 210 located under gates 620 form channel-forming regions of transistors 610. Due to the presence of stress 310L, transistors 610 are stressed transistors. Preferably, the parts of the third portion 210 located on either side of the channel-forming regions are P-doped to form drain and source regions of transistors 610. Transistors 610 are thus P-channel transistors (PMOS). In the channel-forming region, the presence of compressive stress in the drain-source direction (the length direction of the transistors) and, substantially, the lack of stress in the width direction of the transistors, enables to obtain particularly fast P-channel transistors 610.

Preferably, gates 620 also extend over the fourth portions 230.

Preferably, field-effect transistors 630 are formed in and on top of the fourth portions 230. More specifically, the parts of the fourth portions 230 located under gates 620 form channel-forming regions of transistors 630. Transistors 630 may be insulated from one another by the first oxidized portions 140, which may form super shallow trench isolation (SSTI) trenches. Further, gates 625 (second gates) are formed above the first oxidized portions 140 between the fourth portions 230. Thus, insulating gates 650 are positioned in line with gates 625 in the width direction, but are preferably separated from gates 625 by a gap. Preferably, the parts of the fourth portions 230 located on either side of the channel-forming regions are N-type doped to form drain and source regions of transistors 630. Transistors 630 are thus N-channel transistors (NMOS), and enable to form, with P-channel transistors 610, digital circuits. Transistors 630 are not transistors with a stressed channel-forming region.

Preferably, transistors 610 and 630 are of fully depleted SOI (FDSOI) type. By FDSOI transistor, there is here meant that the thickness of their channel-forming region is smaller than 10 nm.

The other elements of the field-effect transistors are not described, the described methods being compatible with current methods of forming field-effect transistors on a portion of a semiconductor layer. In particular, it may be provided for conductive areas in electrical contact with the drain and source regions, that is, contact areas or contacting areas, may be formed, for example epitaxially, on the third portion 210 and on the fourth portions 230, at least on either side of gates 620. Further, preferably, the gates are insulated from semiconductor layer 120 by a gate insulator.

Preferably, in part PCM, phase-change memory cells 640 have been formed. Memory cells 640 are for example located in insulating layers, not shown, covering the structure. Each memory point is coupled, preferably connected, to one of bipolar transistors 545. More specifically, memory cell 640 and bipolar transistor 545 are electrically in series. For each memory cell 640, a via 645 may connect memory cell 640 and the associated bipolar transistor 545.

In the chip in operation, during a step of writing into and/or reading from a phase-change memory, the memory cell(s) 640 concerned by the writing or the reading is/are selected by turning on the bipolar transistor(s) 545 in series with this/these memory cell(s) 640. Bipolar transistors 545 are thus called selection transistors.

In the chip 600 obtained by the above method, the electrical insulations between NMOS transistors 630, formed by the parts 140A of the first oxidized portions 140, and the electrical insulations between the phase-change memory selection bipolar transistors 545, formed by parts 150A of the second oxidized portions 150, result from a single step of oxidation of semiconductor layer 120. As compared with a method in which the electrical insulators would have been obtained at different steps, this enables to decrease the number of steps of forming of these insulators.

Further, the method enables, by not forming first oxidized portions in the third portion, as mentioned hereabove, stress 310L not to be released in the length direction of the stressed PMOS transistors 610. This enables to have higher mechanical stress in the channel-forming region of these PMOS transistors, and may thus allow a better performance of the PMOS transistors. Thus, PMOS transistors 610 are not insulated from one another by SSTI-type trenches, and third portion 210 forms a continuous RX area, PMOS transistors 610 being able to be insulated from one another by insulating gates 650.

Preferably, in the case where semiconductor portions 420C and 420D have been provided in the respective regions 520 and 530, these portions are doped, at this step or at an earlier step, with a same conductivity type (among the two types N and P) as substrate 110 or a doped well formed under insulator 130 under the respective regions 520 and 530. In the case where wells (not shown) are formed under the respective regions 520 and 530, these wells may be electrically insulated from one another by means of insulating trench 510A.

Each of semiconductor portions 420C and 420D may then be topped with a contacting area, forming “bulk strap” or “bulk tap” areas. Applying a potential to the contacting area biases substrate 110 or the well under the concerned region 520, 530. This biasing has the function of electrostatically controlling the respective transistors 610, 630, through insulator 130. Such a control is desirable, for example, to modify the threshold voltage of transistors 610, 630 as a function of a desired compromise between the speed and the power consumption of the transistors.

As indicated hereabove, the semiconductor portions 420C of region 520 are insulated from the third portion 210 by parts 150C of the second oxidized portions 150, and the semiconductor portions 420D of region 530 are insulated from the fourth portions 230 by parts 150D of the second oxidized portions 150. The second oxidized portions 150 form a super shallow trench isolation (SSTI), so that regions 111A and 111B, respectively forming the wells of transistors 610 and 630, can be independently biased since they are insulated from each other by insulating trenches 510A.

Preferably, there have been formed, at the same time as gates 620, gates 620A (third gates) on stacks 430. In the case where areas of electrical contact with the emitter, base, and/or collector regions of bipolar transistors 545 are formed, for example epitaxially, on semiconductor portions 420A, gates 620A enable to form these areas without risking for unwanted conductive bridges to form on stacks 430 and to cause short-circuits between adjacent bipolar transistors 545.

Preferably, in part PW, a transistor 660, having a gate 620B, has also been formed in and on top of semiconductor portion 420B. In other words, transistor 660 has a channel-forming region located in a part of the epitaxial portion 420 located under gate 620B and separated from gate 620B by a gate insulator, not shown. Preferably, transistor 660 has a gate insulator thickness greater than that of transistors 610 and 630. This enables transistor 660 to have a maximum gate-source voltage (beyond which the transistor could be damaged) higher than that of transistors 610 and 620. Gate 620B is preferably formed at the same time as gates 620 and 620A.

Various embodiments and variants have been described. Those skilled in the art will understand that certain features of these various embodiments and variants may be combined, and other variants will occur to those skilled in the art. In particular, an electronic chip with a phase-change memory circuit comprising memory cells coupled to bipolar transistors has been described, but the embodiments may apply to other electronic chips, which do not necessarily comprise cells of a non-volatile memory.

Finally, the practical implementation of the described embodiments and variants is within the abilities of those skilled in the art based on the functional indications given hereabove.

A method of manufacturing an electronic chip (600), the method is summarized as including the successive steps of: —providing a semiconductor layer (120) located on an insulator (130) covering a semiconductor substrate (110); oxidizing first and second portions of the semiconductor layer down to the insulator, to form first oxidized portions (140) and second oxidized portions (150) on the insulator; generating stress (310) in a third portion (210) of the semiconductor layer through which the first and second oxidized portions do not pass, the third portion extending continuously between the second oxidized portions (150); forming cavities (410) extending at least down to the semiconductor substrate through the second oxidized portions and the insulator; and forming first field-effect transistors (610) in and on top of the third portion (210).

An electronic chip (600) is summarized as including: first (140), second (150), and third (210) portions of a semiconductor layer (120) located on an insulator (130) covering a semiconductor substrate (110), the first and second portions of said semiconductor layer being oxidized down to the insulator, the third portion (210) being stressed, not having the first and second oxidized portions passing through it, and continuously extending between first parts (150B) of the second oxidized portions; cavities (410) extending at least down to the semiconductor substrate through the second oxidized portions and the insulator; and first field-effect transistors (610) located in and on top of the third portion (210).

Fourth portions (230) of the semiconductor layer (120) are formed next to the third portion (210), each fourth portion being between two of the first oxidized portions (140) or between one of the first oxidized portions and one of the second oxidized portions (150); and second field-effect transistors (630) are formed in and on top of the fourth portions.

First gates (620) are formed above the third and fourth portions.

Second gates (625) are formed above the first oxidized portions (140) and insulating gates (650) are formed in line with the second gates above the third portion (210).

The fourth portions (230) are positioned next to the third portion (210) in the width direction of the field-effect transistors.

The first transistors (610) have a stressed P channel, and the second transistors (630) have an N channel, for example an unstressed N channel.

Insulating trenches (510) extend through the semiconductor layer (120) and the insulator (130) down to a level located within the semiconductor substrate (110), the insulating trenches include a first insulating trench (510A) between the third portion (210) and the fourth portions (230).

The stress (310) of the third portion (210) results from a change in the composition of the semiconductor layer (120) in said third portion, for example include the forming of a silicon-germanium layer (230) on the third portion, followed by a thermal treatment.

The first oxidized portions are substantially parallel to one another, for example parallel to the width direction of the field-effect transistors; and/or the second oxidized portions are substantially parallel to one another, for example parallel to the width direction of the field-effect transistors; and/or the first oxidized portions are positioned between at least two of the second oxidized portions.

The semiconductor layer (120) is a silicon layer.

The first transistors (610) are of FDSOI type.

Bipolar transistors (545) are formed in at least a first part of the cavities (410), and phase-change memory cells (640) coupled to the bipolar transistors are formed.

Doped emitter, base, and collector semiconductor regions of the bipolar transistors are formed in first epitaxial semiconductor portions (420A) in the at least a first part of the cavities (410).

Third gates (620A) are formed on second parts (150A) of the second oxidized portions (150) between the bipolar transistors (545).

Additional field-effect transistors (660) are formed in and on top of second epitaxial semiconductor portions (420B) in a second part of the cavities (410).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an electronic chip, comprising:
forming a semiconductor layer on an insulator covering a semiconductor substrate, the semiconductor layer having a first surface opposite the insulator along a first direction;
oxidizing first and second portions of the semiconductor layer from the first surface to the insulator along the first direction, to form first oxidized portions and second oxidized portions on the insulator;
generating stress in a third portion of the semiconductor layer through which the first and second oxidized portions do not pass, the third portion extending continuously between the second oxidized portions along a second direction transverse to the first direction;
forming cavities extending along the first direction through the second oxidized portions and the insulator, the cavities at least reaching the semiconductor substrate along the first direction; and
forming first field-effect transistors in and on top of the third portion.

2. The method according to claim 1, further comprising:
forming fourth portions of the semiconductor layer next to the third portion, a first of the fourth portions being between two of the first oxidized portions and a second of the fourth portions being between one of the first oxidized portions and one of the second oxidized portions; and
forming second field-effect transistors in and on top of the fourth portions.

3. The method according to claim 2, further comprising forming first gates above the third and fourth portions along the first direction.

4. The method according to claim 2, further comprising:
forming second gates above the first oxidized portions along the first direction; and
forming insulating gates in line with the second gates along a third direction transverse to the first and second directions and above the third portion along the first direction.

5. The method according to claim 2, wherein the fourth portions are positioned next to the third portion along a third direction transverse to the first and second directions.

6. The method according to claim 2, wherein the first transistors have a stressed P channel, and the second transistors have an N channel.

7. The method according to claim 2, wherein insulating trenches extend along the first direction through the semiconductor layer and the insulator, into the semiconductor substrate, the insulating trenches including a first insulating trench between the third portion and the fourth portions.

8. An electronic chip, comprising:
an insulator covering a semiconductor substrate;
first, second, and third portions of a semiconductor layer on the insulator, the first and second portions of the semiconductor layer being oxidized along a first direction from a first surface of the semiconductor layer opposite the insulator to the insulator, the third portion being stressed and continuously extending between first parts of the second oxidized portions;
cavities extending along the first direction at least to the semiconductor substrate through the second oxidized portions and the insulator; and
first field-effect transistors located in and on the third portion.

9. The electronic chip according to claim 8, wherein the stress of the third portion results from a change in a composition of the semiconductor layer in the third portion.

10. The electronic chip according to claim 9, wherein the change in the composition of the semiconductor layer includes the forming of a silicon-germanium layer on the third portion, followed by a thermal treatment.

11. The electronic chip according to claim 8, wherein:
the first oxidized portions are substantially parallel to one another; and
the second oxidized portions are substantially parallel to one another; and
the first oxidized portions are positioned between at least two of the second oxidized portions.

12. The electronic chip according to claim 8, wherein the semiconductor layer is a silicon layer.

13. The electronic chip according to claim 8, wherein the first transistors are of FDSOI type.

14. The electronic chip according to claim 8, wherein bipolar transistors are formed in at least a first part of the cavities, and phase-change memory cells are coupled to the bipolar transistors.

15. The electronic chip according to claim 14, wherein doped emitter, base, and collector semiconductor regions of the bipolar transistors are formed in first epitaxial semiconductor portions in the at least a first part of the cavities.

16. The electronic chip according to claim 14, wherein third gates are formed on second parts of the second oxidized portions between the bipolar transistors.

17. The electronic chip according to claim 8, wherein second field-effect transistors are formed in and on second epitaxial semiconductor portions in a second part of the cavities.

18. A device, comprising:
an insulator entirely covering a substrate;
a semiconductor layer opposite the insulator from the substrate along a first direction, the semiconductor layer having a first side opposite a second side along a second direction transverse to the first direction;
a first plurality of oxidized portions and a second plurality of oxidized portions of the semiconductor layer;
a third portion of the semiconductor layer extending along the second direction from the second side to a first surface of each first oxidized portion, each first surface being between the first side and the second side along the second direction;
a fourth plurality of portions of the semiconductor layer between the first and second oxidized portions, the fourth portions each having a first surface coplanar with the first surface of each first oxidized portion;
a first cavity extending between third portion and the fourth plurality of portions, the first cavity extending along the first direction entirely through the third portion and the insulator; and
a first field-effect transistor in and on the third portion.

19. The device according to claim 18, wherein the second plurality of oxidized portions extend from the first side to the second side along the second direction.

20. The device according to claim 18, wherein the first and second pluralities of oxidized portions each have a thickness along the first direction greater than a thickness of the semiconductor layer along the first direction.
